(19) United States
(12) Patent Application Publication
(10) Pub. No.: US 2025/0372954 A1
(43) Pub. Date: Dec. 4, 2025

(54) SEMICONDUCTOR OPTICAL GAIN DEVICE AND OPTICAL SEMICONDUCTOR APPARATUS

(71) Applicant: Mitsubishi Electric Corporation, Tokyo (JP)

(72) Inventors: Kosuke SHINOHARA, Chiyoda-ku, Tokyo (JP); Satoshi NISHIKAWA, Chiyoda-ku, Tokyo (JP)

(73) Assignee: Mitsubishi Electric Corporation, Tokyo (JP)

(21) Appl. No.: 18/876,678

(22) PCT Filed: Jul. 8, 2022
(86) PCT No.: PCT/JP2022/027114

§ 371 Date: Dec. 19, 2024

(51) Int. Cl. H01S 5/20

(52) U.S. Cl. CPC H01S 5/2027; H01S 5/2031

(57) ABSTRACT

A semiconductor optical gain device includes a substrate, an active portion, and a passive portion. The active portion includes an active layer. The passive portion includes a first core layer, a reflection portion, and a top surface. The first core layer is formed with a first grating coupler. The first grating coupler diffracts light output from the active layer to generate a first diffraction light and a second diffraction light. The reflection portion is disposed between the first grating coupler and the substrate to reflect the second diffraction light toward the top surface of the passive portion, and includes at least one air layer.

### TECHNICAL FIELD

The present disclosure relates to a semiconductor optical gain device and an optical semiconductor apparatus.

### BACKGROUND ART

U.S. Patent Application Publication No. 2021/0181427 (PTL 1) discloses an integrated grating coupler system. The integrated grating coupler system includes a first optical chip and a second optical chip. The first optical chip includes an InP substrate, an InGaAsP waveguide layer formed on the InP substrate, and an IP cladding layer formed on the InGaAsP waveguide layer. The InGaAsP waveguide layer is formed with a first grating coupler. The second optical chip includes a Si substrate, an embedded SiO₂ layer formed on the Si substrate, a Si waveguide layer formed on the embedded SiO₂ layer, and a SiO₂ cladding layer formed on the Si waveguide layer. The Si waveguide layer is formed with a second grating coupler.

The first optical chip is mounted on the second optical chip. The InP substrate of the first optical chip faces the second optical chip. The first grating coupler is a long period grating, and diffracts light propagating through the InGaAsP waveguide layer of the first optical chip only toward the InP substrate. The second grating coupler is optically coupled to the first grating coupler. The light diffracted by the first grating coupler is coupled to the second grating coupler, and propagates through the Si waveguide.

### CITATION LIST

### Patent Literature

PTL 1: U.S. Patent Application Publication No. 2021/0181427

### SUMMARY OF INVENTION

### Technical Problem

However, the InP substrate is the thickest component in the first optical chip, and has the largest thickness variation in the first optical chip. When the thickness of the InP substrate varies, the position of light emitted from the first optical chip will vary. Therefore, in the integrated grating coupler system disclosed in PTL 1, it is necessary to improve the mounting accuracy of the first optical chip on the second optical chip.

The present disclosure has been made in view of the above-described problems, and an object thereof is to provide a semiconductor optical gain device and an optical semiconductor apparatus capable of relaxing a mounting accuracy of the semiconductor optical gain device on an optical waveguide chip and improving a coupling efficiency of light from the semiconductor optical gain device to the optical waveguide chip.

### Solution to Problem

A semiconductor optical gain device according to the present disclosure includes a substrate, an active portion formed on the substrate, and a passive portion formed on the substrate. The active portion includes an active layer. The passive portion includes a first core layer optically coupled to the active layer, a reflection portion, and a top surface opposite to the substrate with respect to the first core layer. The first core layer is formed with a first grating coupler. The first grating coupler diffracts light output from the active layer to generate a first diffraction light traveling from the first grating coupler toward the top surface and a second diffraction light traveling from the first grating coupler toward the substrate. The reflection portion is disposed between the first grating coupler and the substrate to reflect the second diffraction light toward the top surface of the passive portion, and includes at least one air layer.

An optical semiconductor apparatus of the present disclosure includes a semiconductor optical gain device of the present disclosure and an optical waveguide chip disposed to face the top surface of the passive portion. The optical waveguide chip includes a second core layer. The second core layer is formed with a second grating coupler optically coupled to the first grating coupler.

### Advantageous Effects of Invention

The variation in the position of the first diffraction light and the second diffraction light emitted from the semiconductor optical gain device can be reduced. The mounting accuracy of the semiconductor optical gain device on the optical waveguide chip can be relaxed. Further, the coupling efficiency of light from the semiconductor optical gain device to the optical waveguide chip can be improved.

### BRIEF DESCRIPTION OF DRAWINGS

FIG. 1 is a cross-sectional view schematically illustrating a semiconductor optical gain device according to a first embodiment;

FIG. 2A is a partially enlarged cross-sectional view schematically illustrating a region IIA illustrated in FIG. 1 of the semiconductor optical gain device according to the first embodiment:

FIG. 2B is a partially enlarged cross-sectional view schematically illustrating a first modification of a reflection portion of the semiconductor optical gain device according to the first embodiment;

FIG. 2C is a partially enlarged cross-sectional view schematically illustrating a second modification of the reflection portion of the semiconductor optical gain device according to the first embodiment;

FIG. 3 is a partially enlarged cross-sectional view schematically illustrating a step in a method of manufacturing a passive portion of the semiconductor optical gain device according to the first embodiment;

FIG. 4 is a partially enlarged cross-sectional view schematically illustrating a step in the method of manufacturing a passive portion of the semiconductor optical gain device according to the first embodiment;

FIG. 5 is a partially enlarged cross-sectional view schematically illustrating a step subsequent to the steps illustrated in FIGS. 3 and 4 in the method of manufacturing a passive portion of the semiconductor optical gain device according to the first embodiment;

FIG. 6 is a partially enlarged cross-sectional view schematically illustrating a step subsequent to the steps illustrated in FIGS. 3 and 4 in the method of manufacturing a passive portion of the semiconductor optical gain device according to the first embodiment;

FIG. 7 is a partially enlarged cross-sectional view schematically illustrating a step subsequent to the steps illustrated in FIGS. 5 and 6 in the method of manufacturing a passive portion of the semiconductor optical gain device according to the first embodiment;

FIG. 8 is a partially enlarged cross-sectional view schematically illustrating a step subsequent to the steps illustrated in FIGS. 5 and 6 in the method of manufacturing a passive portion of the semiconductor optical gain device according to the first embodiment;

FIG. 9 is a partially enlarged cross-sectional view schematically illustrating a step subsequent to the steps illustrated in FIGS. 7 and 8 in the method of manufacturing a passive portion of the semiconductor optical gain device according to the first embodiment;

FIG. 10 is a partially enlarged cross-sectional view schematically illustrating a step subsequent to the steps illustrated in FIGS. 7 and 8 in the method of manufacturing a passive portion of the semiconductor optical gain device according to the first embodiment;

FIG. 11 is a graph illustrating a reflectance of a reflection portion of a semiconductor optical gain device according to a comparative example;

FIG. 12 is a graph illustrating the reflectance of a reflection portion of the semiconductor optical gain device according to a first example, a second example, and a third example;

FIG. 13 is a cross-sectional view schematically illustrating a semiconductor optical gain device according to a second embodiment;

FIG. 14 is a partially enlarged cross-sectional view schematically illustrating a region XIV illustrated in FIG. 13 of the semiconductor optical gain device according to the second embodiment;

FIG. 15 is a schematic partially enlarged plan view of a reflection portion of the semiconductor optical gain device according to the second embodiment;

FIG. 16 is a partially enlarged cross-sectional view schematically illustrating a step in a method of manufacturing a passive portion of the semiconductor optical gain device according to the second embodiment;

FIG. 17 is a partially enlarged cross-sectional view schematically illustrating a step in the method of manufacturing a passive portion of the semiconductor optical gain device according to the second embodiment;

FIG. 18 is a partially enlarged cross-sectional view schematically illustrating a step subsequent to the steps illustrated in FIGS. 16 and 17 in the method of manufacturing a passive portion of the semiconductor optical gain device according to the second embodiment;

FIG. 19 is a partially enlarged cross-sectional view schematically illustrating a step subsequent to the steps illustrated in FIGS. 16 and 17 in the method of manufacturing a passive portion of the semiconductor optical gain device according to the second embodiment;

FIG. 20 is a partially enlarged cross-sectional view schematically illustrating a step subsequent to the steps illustrated in FIGS. 18 and 19 in the method of manufacturing a passive portion of the semiconductor optical gain device according to the second embodiment;

FIG. 21 is a partially enlarged cross-sectional view schematically illustrating a step subsequent to the steps illustrated in FIGS. 18 and 19 in the method of manufacturing a passive portion of the semiconductor optical gain device according to the second embodiment;

FIG. 22 is a partially enlarged cross-sectional view schematically illustrating a step subsequent to the steps illustrated in FIGS. 20 and 21 in the method of manufacturing a passive portion of the semiconductor optical gain device according to the second embodiment;

FIG. 23 is a partially enlarged cross-sectional view schematically illustrating a step subsequent to the steps illustrated in FIGS. 20 and 21 in the method of manufacturing a passive portion of the semiconductor optical gain device according to the second embodiment;

FIG. 24 is a partially enlarged cross-sectional view schematically illustrating a step subsequent to the steps illustrated in FIGS. 22 and 23 in the method of manufacturing a passive portion of the semiconductor optical gain device according to the second embodiment;

FIG. 25 is a partially enlarged cross-sectional view schematically illustrating a step subsequent to the steps illustrated in FIGS. 22 and 23 in the method of manufacturing a passive portion of the semiconductor optical gain device according to the second embodiment;

FIG. 26 is a cross-sectional view schematically illustrating a semiconductor optical gain device according to a third embodiment;

FIG. 27 is a partially enlarged cross-sectional view schematically illustrating the semiconductor optical gain device according to the third embodiment taken along a cross-sectional line XXVI-XXVI illustrated in FIG. 26;

FIG. 28 is a partially enlarged cross-sectional view schematically illustrating the semiconductor optical gain device according to the third embodiment taken along a cross-sectional line XXVIII-XXVIII illustrated in FIG. 27;

FIG. 29 is a partially enlarged cross-sectional view schematically illustrating the semiconductor optical gain device according to the third embodiment taken along a cross-sectional line XXIX-XXIX illustrated in FIG. 27;

FIG. 30 is a partially enlarged cross-sectional view schematically illustrating the semiconductor optical gain device according to the third embodiment taken along a cross-sectional line XXX-XXX illustrated in FIG. 27;

FIG. 31 is a partially enlarged cross-sectional view schematically illustrating a step in the method of manufacturing a passive portion of the semiconductor optical gain device according to the third embodiment;

FIG. 32 is a partially enlarged cross-sectional view schematically illustrating a step in the method of manufacturing a passive portion of the semiconductor optical gain device according to the third embodiment;

FIG. 33 is a partially enlarged cross-sectional view schematically illustrating a step in the method of manufacturing a passive portion of the semiconductor optical gain device according to the third embodiment;

FIG. 34 is a partially enlarged cross-sectional view schematically illustrating a step subsequent to the steps illustrated in FIGS. 31 to 33 in the method of manufacturing a passive portion of the semiconductor optical gain device according to the third embodiment;

FIG. 35 is a partially enlarged cross-sectional view schematically illustrating a step subsequent to the steps illustrated in FIGS. 31 to 33 in the method of manufacturing a passive portion of the semiconductor optical gain device according to the third embodiment:

FIG. 36 is a partially enlarged cross-sectional view schematically illustrating a step subsequent to the steps illustrated in FIGS. 31 to 33 in the method of manufacturing a passive portion of the semiconductor optical gain device according to the third embodiment;

FIG. 37 is a partially enlarged cross-sectional view schematically illustrating a step subsequent to the steps illustrated in FIGS. 34 to 36 in the method of manufacturing a passive portion of the semiconductor optical gain device according to the third embodiment;

FIG. 38 is a partially enlarged cross-sectional view schematically illustrating a step subsequent to the steps illustrated in FIGS. 34 to 36 in the method of manufacturing a passive portion of the semiconductor optical gain device according to the third embodiment;

FIG. 39 is a partially enlarged cross-sectional view schematically illustrating a step subsequent to the steps illustrated in FIGS. 34 to 36 in the method of manufacturing a passive portion of the semiconductor optical gain device according to the third embodiment;

FIG. 40 is a partially enlarged cross-sectional view schematically illustrating a process subsequent to the process illustrated in FIGS. 37 to 39 in the method of manufacturing a passive portion of the semiconductor optical gain device according to the third embodiment;

FIG. 41 is a partially enlarged cross-sectional view schematically illustrating a step subsequent to the steps illustrated in FIGS. 37 to 39 in the method of manufacturing a passive portion of the semiconductor optical gain device according to the third embodiment;

FIG. 42 is a partially enlarged cross-sectional view schematically illustrating a step subsequent to the steps illustrated in FIGS. 37 to 39 in the method of manufacturing a passive portion of the semiconductor optical gain device according to the third embodiment;

FIG. 43 is a partially enlarged cross-sectional view schematically illustrating a step subsequent to the steps illustrated in FIGS. 40 to 42 in the method of manufacturing a passive portion of the semiconductor optical gain device according to the third embodiment;

FIG. 44 is a partially enlarged cross-sectional view schematically illustrating a step subsequent to the steps illustrated in FIGS. 40 to 42 in the method of manufacturing a passive portion of the semiconductor optical gain device according to the third embodiment;

FIG. 45 is a partially enlarged cross-sectional view schematically illustrating a step subsequent to the steps illustrated in FIGS. 40 to 42 in the method of manufacturing a passive portion of the semiconductor optical gain device according to the third embodiment; and

FIG. 46 is a cross-sectional view schematically illustrating an optical semiconductor apparatus according to a fourth embodiment.

### DESCRIPTION OF EMBODIMENTS

Hereinafter, embodiments of the present disclosure will be described. The same components are denoted by the same reference numerals, and the description thereof will not be repeated.

### First Embodiment

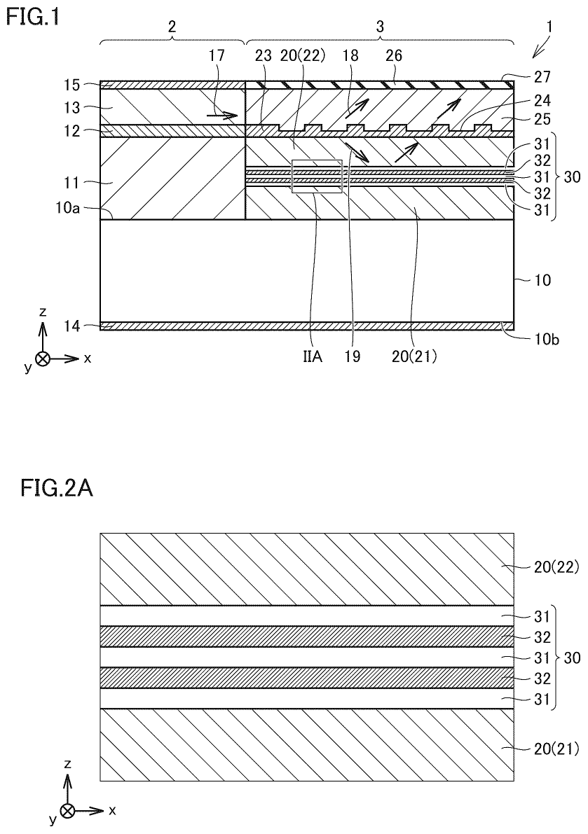

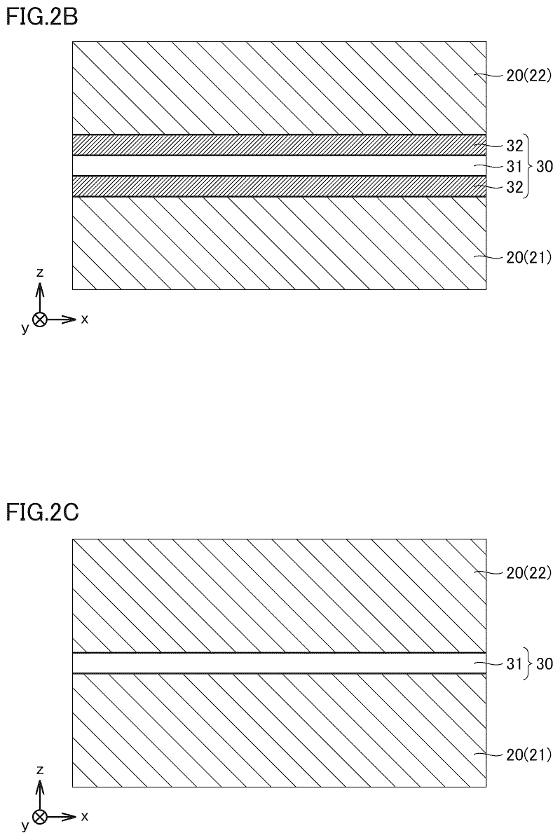

A semiconductor optical gain device 1 according to a first embodiment will be described with reference to FIGS. 1 and 2A. The semiconductor optical gain device 1 includes a substrate 10, an active portion 2, and a passive portion 3.

With reference to FIG. 1, the substrate 10 is a semiconductor substrate formed of a compound semiconductor such as InP or GaAs. The substrate 10 includes a main surface 10a and a main surface 10b opposite to the main surface 10a. The main surface 10a and the main surface 10b each extend in the x direction and the y direction perpendicular to the x direction. The normal direction of the main surface 10a and the normal direction of the main surface 10b are each in the z direction perpendicular to the x direction and the y direction.

With reference to FIG. 1, the active portion 2 is formed on the substrate 10. The active portion 2 outputs light 17. The output direction of the light 17 from the active portion 2 is in the x direction, and the width direction of the active portion 2 is in the y direction. The active portion 2 includes a lower cladding layer 11, an active layer 12, an upper cladding layer 13, an electrode 14, and an electrode 15. The lower cladding layer 11 is formed on the main surface 10a of the substrate 10 by, for example, epitaxial growth. The active layer 12 is formed on the lower cladding layer 11 by, for example, epitaxial growth. The upper cladding layer 13 is formed on the active layer 12 by, for example, epitaxial growth. The electrode 14 is formed on the main surface 10b of the substrate 10 by, for example, vapor deposition. The electrode 15 is formed on the upper cladding layer 13 by, for example, vapor deposition.

The active layer 12 has a higher refractive index and a smaller band gap energy than the lower cladding layer 11 and the upper cladding layer 13. The active layer 12 is formed of, for example, a compound semiconductor such as AlGaInAs or InGaAsP. The lower cladding layer 11 and the upper cladding layer 13 are formed of, for example, a compound semiconductor such as IrP or GaAs. When a current is injected from the electrodes 14 and 15, an induced emission phenomenon occurs in the active layer 12. The light 17 is output from the active layer 12. The active portion 2 is a laser diode or a semiconductor optical amplifier (SOA).

With reference to FIGS. 1 and 2A, the passive portion 3 is formed on the main surface 10a of the substrate 10, The propagation direction of light in the passive portion 3 is in the x direction, and the width direction of the passive portion 3 is in the y direction. The passive portion 3 includes a lower cladding layer 20, a first core layer 23, an upper cladding layer 25, an insulating layer 26, and a reflection portion 30.

The lower cladding layer 20 is formed on the main surface 10a of the substrate 10 by, for example, epitaxial growth. The lower cladding layer 20 is disposed between the first core layer 23 and the substrate 10. The lower cladding layer 20 includes a first lower cladding sublayer 21 and a second lower cladding sublayer 22. The first lower cladding sublayer 21 is disposed between the reflection portion 30 and the substrate 10. The second lower cladding sublayer 22 is disposed between the reflection portion 30 and the first core layer 23.

The first core layer 23 is formed on the lower cladding layer 20 (more specifically, on the second lower cladding sublayer 22) by, for example, epitaxial growth. The longitudinal direction of the first core layer 23 is in the x direction, and the width direction of the first core layer 23 is in the y direction. The first core layer 23 is optically coupled to the active layer 12. The light 17 output from the active layer 12 is coupled to the first core layer 23 and propagates through the first core layer 23. The passive portion 3 includes a passive waveguide.

The upper cladding layer 25 is formed on the first core layer 23 by, for example, epitaxial growth. The insulating layer 26 is formed on the upper cladding layer 25 by, for example, chemical vapor deposition (CVD) or sputtering. The insulating layer 26 is a silicon oxide layer (SiO₂ layer). The insulating layer 26 includes a top surface 27 of the passive portion 3. The top surface 27 of the passive portion 3 is a surface of the passive portion 3 opposite to the substrate 10 with respect to the first core layer 23. The top surface 27 of the passive portion 3 extends in the x direction and the y direction. The normal direction of the top surface 27 of the passive portion 3 is in the z direction.

The first core layer 23 has a higher refractive index than the lower cladding layer 20 (more specifically, the second lower cladding sublayer 22) and the upper cladding layer 25. The first core layer 23 has a larger bandgap energy than the active layer 12. The first core layer 23 has a larger bandgap energy than the energy of the light 17 output from the active layer 12. The first core layer 23 is formed of, for example, a compound semiconductor such as AlGaInAs or InGaAsP. The lower cladding layer 20 and the upper cladding layer 25 are formed of, for example, a compound semiconductor such as hit or GaAs. The lower cladding layer 20 may be formed of the same material as the lower cladding layer 11. The upper cladding layer 25 may be formed of the same material as the upper cladding layer 13.

The first core layer 23 is formed with a first grating coupler 24. The first grating coupler 24 diffracts the light 17 output from the active layer 12 to generate a first diffraction light 18 traveling from the first grating coupler 24 toward the top surface 27 of the passive portion 3 and a second diffraction light 19 traveling from the first grating coupler 24 toward the substrate 10 (or the reflection portion 30).

The grating pitch of the first grating coupler 24 is determined in such a manner that the second diffraction light 19 reflected by the reflection portion 30 is emitted from the top surface 27 of the passive portion 3 to the outside of the semiconductor optical gain device 1, in other words, in such a manner that the second diffraction light 19 reflected by the reflection portion 30 is not totally reflected by the top surface 27 of the passive portion 3. The grating pitch of the first grating coupler 24 is shorter than the wavelength of the light 17, and the first grating coupler 24 is a short period grating. For example, an incident angle of the second diffraction light 19 to the reflection portion 30 is less than 18°, and the grating pitch of the first grating coupler 24 is less than 0.58 μm. In the present specification, the incident angle of the second diffraction light 19 to the reflection portion 30 is defined as an angle between an incident direction of the second diffraction light 19 to the reflection portion 30 and a normal line (z direction) of the reflection portion 30.

The reflection portion 30 is disposed between the first grating coupler 24 and the substrate 10. The reflection portion 30 is disposed inside the lower cladding layer 20. Specifically, the reflection portion 30 is formed on the first lower cladding sublayer 21, and is disposed between the first lower cladding sublayer 21 and the second lower cladding sublayer 22. The reflection portion 30 reflects the second diffraction light 19 diffracted by the first grating coupler 24 toward the top surface 27 of the passive portion 3. Therefore, the light diffracted by the first grating coupler 24 (the first diffraction light 18 and the second diffraction light 19) among the light 17 output from the active layer 12 is emitted from the top surface 27 of the passive portion 3 to the outside of the semiconductor optical gain device 1.

As illustrated in FIGS. 1 and 2A, the reflection portion 30 is, for example, a multilayer reflection film in which an air layer 31 serving as a low refractive index layer and a semiconductor layer 32 serving as a high refractive index layer are alternately stacked. The reflection portion 30 is, for example, a distributed Bragg reflector (DBR). The number of the air layers 31 included in the reflection portion 30 is not limited to two or more, and may be one as illustrated in FIGS. 2B and 2C. In other words, the reflection portion 30 may include at least one air layer 31. When the number of the air layers 31 included in the reflection portion 30 is one, the one air layer 31 may be disposed between the two semiconductor layers 32 as illustrated in FIG. 2B, or the one air layer 31 may be disposed between the first lower cladding sublayer 21 and the second lower cladding sublayer 22 when the semiconductor layer 32 is not included in the reflection portion 30 as illustrated in FIG. 2C. When the number of the air layers 31 included in the reflection portion 30 is two, the number of the semiconductor layers 32 included in the reflection portion 30 is one or more. When the number of the air layers 31 included in the reflection portion 30 is three or more, the reflection portion 30 includes a plurality of semiconductor layers 32.

The semiconductor layer 32 may be formed of the same material as the lower cladding layer 20. The semiconductor layer 32 may be formed of the same material as the first lower cladding sublayer 21, or may be formed of the same material as the second lower cladding sublayer 22. The semiconductor layer 32 is formed of, for example, a compound semiconductor such as InP or GaAs. The semiconductor layer 32 is supported by, for example, the lower cladding layer 11.

The thickness of the air layer 31 and the thickness of the semiconductor layer 32 are determined in such a manner that the reflectance of the reflection portion 30 with respect to the second diffraction light 19 is maximum, for example. The thickness of the semiconductor layer 32 may be larger than a reference thickness of the semiconductor layer 32 at which the reflectance of the reflection portion 30 with respect to the second diffraction light 19 is maximum. Therefore, the mechanical strength of the reflection portion 30 is improved, and thereby the mechanical strength of the semiconductor optical gain device 1 is improved.

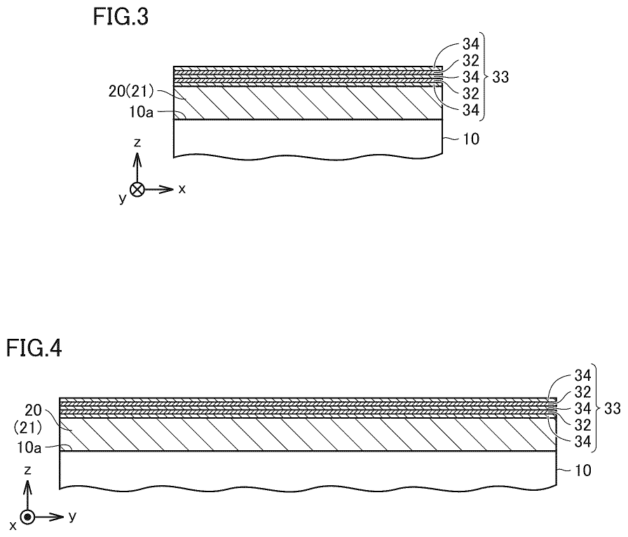

The active portion 2 of the semiconductor optical gain device 1 is manufactured by a known method. An example method of manufacturing the passive portion 3 of the semiconductor optical gain device 1 according to the present embodiment will be described with reference to FIGS. 3 to 10.

With reference to FIGS. 3 and 4, the first lower cladding sublayer 21 is formed on the main surface 10a of the substrate 10 by epitaxial growth. The first lower cladding sublayer 21 is formed of, for example, a compound semiconductor such as InP or GaAs.

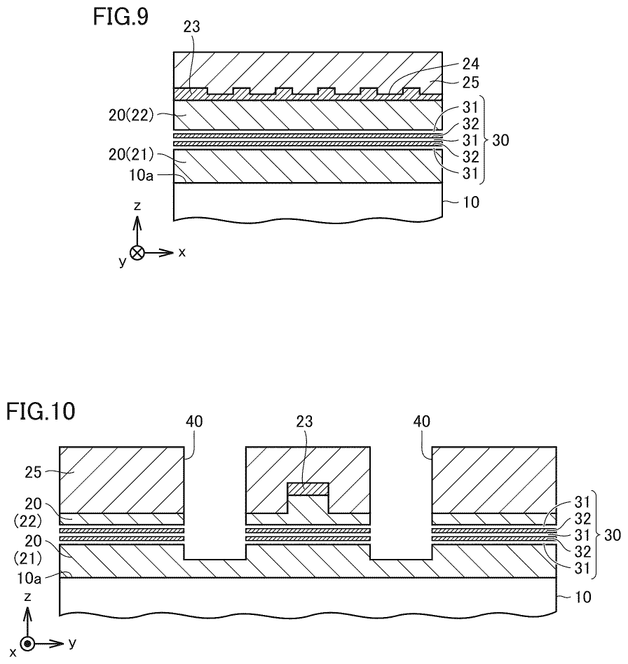

With reference to FIGS. 3 and 4, a multilayer film 33 is formed on the main surface 10a of the substrate 10 by epitaxial growth. The multilayer film 33 is formed by alternately stacking the semiconductor layer 32 and a sacrificial layer 34. The sacrificial layer 34 is formed of a material having an etching rate higher than that of the semiconductor layer 32 with respect to an etchant used in the etching steps illustrated in FIGS. 9 and 10. For example, the semiconductor layer 32 is formed of a compound semiconductor such as InP or GaAs. The sacrificial layer 34 is formed of a compound semiconductor such as InGaAsP, AlGaInAs, InGaAs, or AlInAs.

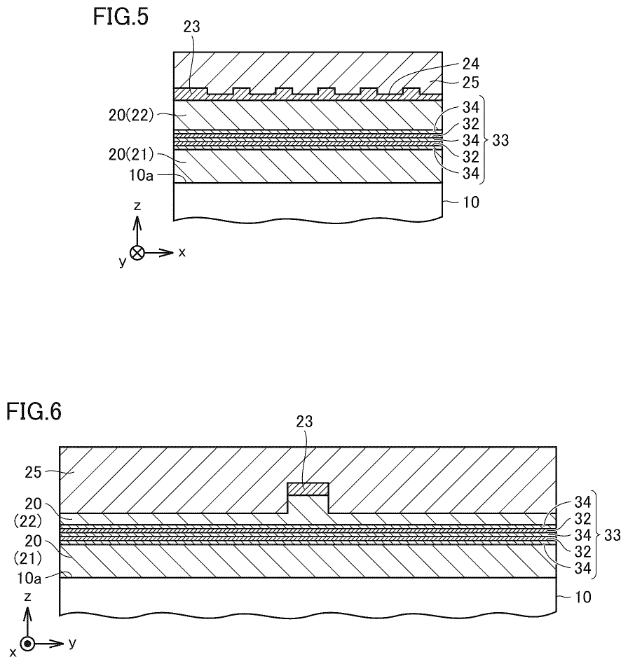

With reference to FIGS. 5 and 6, the second lower cladding sublayer 22 is formed on the multilayer film 33 by epitaxial growth. The second lower cladding sublayer 22 is formed of, for example, the same material as the first lower cladding sublayer 21. The second lower cladding sublayer 22 is formed of, for example, a compound semiconductor such as InP or GaAs. The first core layer 23 is formed on the lower cladding layer 20 by epitaxial growth. A mesa structure is formed in the second lower cladding sublayer 22 and the first core layer 23 by etching the second lower cladding sublayer 22 and the first core layer 23. The first grating coupler 24 is formed on the first core layer 23 by etching the first core layer 23. The upper cladding layer 25 is formed on the second lower cladding sublayer 22 and the first core layer 23 by epitaxial growth. The mesa structure is embedded in the upper cladding layer 25.

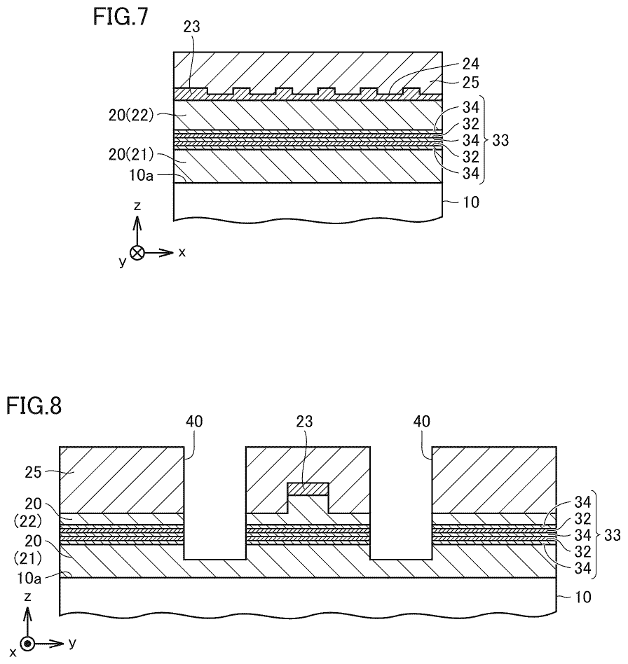

With reference to FIGS. 7 and 8, a groove 40 is formed on both sides of the first core layer 23 by etching the upper cladding layer 25, the second lower cladding sublayer 22, the multilayer film 33, and the first lower cladding sublayer 21. A part of the multilayer film 33 is exposed from the groove 40. Holes may be formed instead of the groove 40.

With reference to FIGS. 9 and 10, an etchant (for example, an etching solution) is introduced into the groove 40, and thereby the sacrificial layer 34 of the multilayer film 33 is selectively etched by the etchant. Since the semiconductor layer 32 has an etching rate lower than that of the sacrificial layer 34 with respect to the etchant, it is hardly etched by the etchant. The sacrificial layer 34 becomes the air layer 31, and the multilayer film 33 becomes the reflection portion 30. The insulating layer 26 is formed on the upper cladding layer 25 by, for example, chemical vapor deposition (CVD) or sputtering. Thus, the passive portion 3 of the semiconductor optical gain device 1 is obtained.

The operations of the semiconductor optical gain device 1 will be described. When a current is injected from the electrodes 14 and 15 into the active layer 12, an induced emission phenomenon occurs in the active layer 12. Light 17 is output from the active layer 12. The light 17 is coupled to the first core layer 23 and propagates through the first core layer 23. The first grating coupler 24 diffracts the light 17 to generate a first diffraction light 18 and a second diffraction light 19. The reflection portion 30 reflects the second diffraction light 19 toward the top surface 27 of the passive portion 3. The first diffraction light 18 and the second diffraction light 19 are emitted from the top surface 27 of the passive portion 3.

The function of the semiconductor optical gain device 1 will be described.

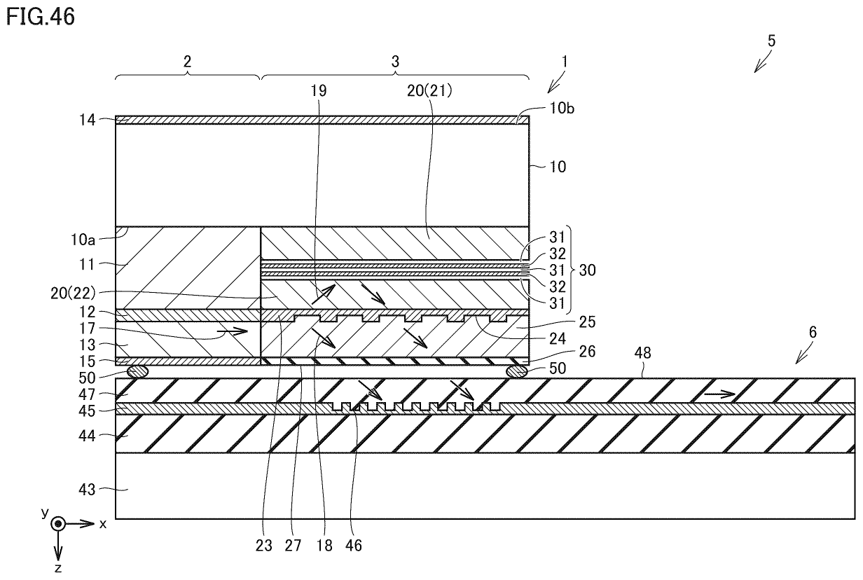

The first diffraction light 18 travels through the upper cladding layer 25, and is emitted from the semiconductor optical gain device 1. The second diffraction light 19 travels through the second lower cladding sublayer 22, the first core layer 23, and the upper cladding layer 25, and is emitted from the semiconductor optical gain device 1. The thickness of the upper cladding layer 25, the thickness of the first core layer 23, and the thickness of the second lower cladding sublayer 22 are each sufficiently smaller than the thickness of the substrate 10. Therefore, the thickness variation of the upper cladding layer 25, the thickness variation of the first core layer 23, and the thickness variation of the second lower cladding sublayer 22 are each sufficiently smaller than the thickness variation of the substrate 10. The first diffraction light 18 and the second diffraction light 19 are emitted from the semiconductor optical gain device 1 without travelling through the substrate 10 having the largest thickness variation in the semiconductor optical gain device 1. The variation in the position of the first diffraction light 18 and the second diffraction light 19 emitted from the semiconductor optical gain device 1 is reduced. The mounting accuracy of the semiconductor optical gain device 1 on the optical waveguide chip 6 (see FIG. 46) can be relaxed.

In addition, since the reflection portion 30 includes at least one air layer 31, the reflectance of the reflection portion 30 with respect to the second diffraction light 19 is increased. Therefore, the coupling efficiency of light from the semiconductor optical gain device 1 to the optical waveguide chip 6 can be improved.

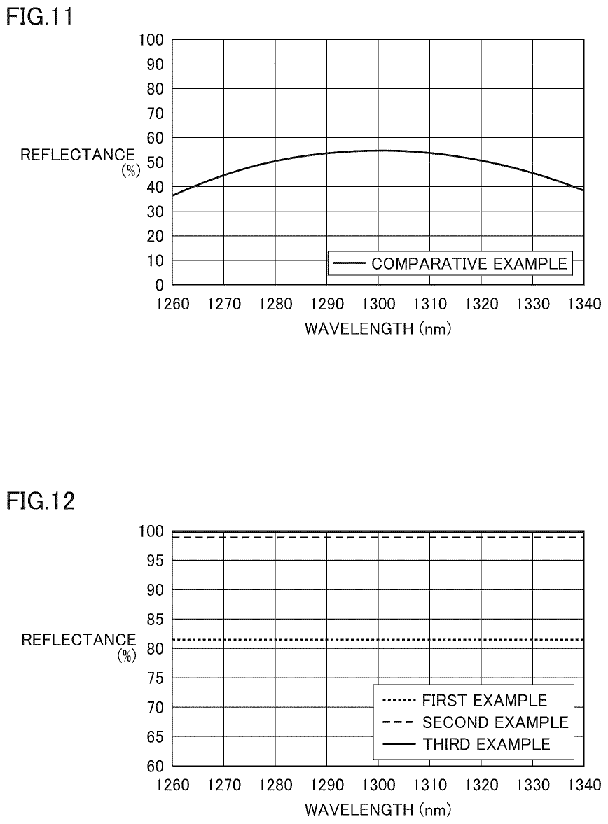

With reference to FIGS. 11 and 12, the improvement on the coupling efficiency of light from the semiconductor optical gain device 1 to the optical waveguide chip 6 in the present embodiment will be described by comparing a semiconductor optical gain device according to a comparative example with the semiconductor optical gain device 1 according to the first to third examples which is an example of the semiconductor optical gain device 1 according to the present embodiment.

The semiconductor optical gain device according to the comparative example has the same configuration as the semiconductor optical gain device 1 according to the present embodiment, but is different in the configuration of the reflection portion 30. In the semiconductor optical gain device according to the comparative example, the reflection portion 30 is a multilayer reflection film in which an InGaAsP layer serving as a high refractive index layer and an InP layer serving as a low refractive index layer are alternately stacked. The reflection portion 30 according to the comparative example does not include an air layer 31 which serves as a low refractive index layer. The reflection portion 30 according to the comparative example has a thirty-layer structure. The wavelength of the second diffraction light 19 is 1300 nm, the refractive index of the InGaAsP layer is 3.41, the refractive index of the InP layer is 3.21, and the incident angle of the second diffraction light 19 to the reflection portion 30 is 12.7°. The thickness of the InGaAsP layer and the thickness of the InP layer are determined in such a manner that the reflectance of the reflection portion 30 with respect to the second diffraction light 19 is maximum. As illustrated in FIG. 11, the reflectance of the reflection portion 30 of the comparative example with respect to the second diffraction light 19 is about 55%.

In contrast, in the semiconductor optical gain device 1 according to the first example, the reflection portion 30 is a multilayer reflection film in which an InP layer (the semiconductor layer 32) serving as a high refractive index layer, an air layer 31 serving as a low refractive index layer, and an InP layer (the semiconductor layer 32) serving as a high refractive index layer are stacked. In other words, the number of the air layers 31 included in the reflection portion 30 of the first example is one, the number of the InP layers (the semiconductor layer 32) included in the reflection portion 30 of the first example is two, and thus the reflection portion 30 of the first example has a three-layer structure.

In the semiconductor optical gain device 1 according to the second example and the semiconductor optical gain device 1 according to the third example, the reflection portion 30 is a multilayer reflection film in which an InP layer (the semiconductor layer 32) serving as a high refractive index layer and an air layer 31 serving as a low refractive index layer are alternately laminated. The number of the air layers 31 included in the reflection portion 30 of the second example is two, the number of the InP layers (the semiconductor layer 32) included in the reflection portion 30 of the second example is three, and thus the reflection portion 30 of the second example has a five-layer structure. The number of the air layers 31 included in the reflection portion 30 of the third example is three, the number of the InP layers (the semiconductor layer 32) included in the reflection portion 30 of the third example is four, and thus the reflection portion 30 of the third example has a seven-layer structure.

In each of the first to third examples, the wavelength of the second diffraction light 19 is 1300 nm, the refractive index of the air layer 31 is 1.00, the refractive index of the InP layer is 3.21, and the incident angle of the second diffraction light 19 to the reflection portion 30 is 12.7°. The thickness of the air layer 31 and the thickness of the InP layer (the semiconductor layer 32) are determined in such a manner that the reflectance of the reflection portion 30 with respect to the second diffraction light 19 is maximum. As illustrated in FIG. 12, the reflectance of the reflection portion 30 of the first example with respect to the second diffraction light 19 is about 81.5%, the reflectance of the reflection portion 30 of the second example with respect to the second diffraction light 19 is about 98.9%, and the reflectance of the reflection portion 30 of the third example with respect to the second diffraction light 19 is about 99.9%.

From the first to third examples and the comparative example, it can be seen that if the reflection portion 30 includes at least one air layer 31, the reflectance of the reflection portion 30 with respect to the second diffraction light 19 is greatly improved. The reason is that the refractive index difference between the low refractive index layer (the air layer 31) of the reflection portion 30 and an layer adjacent to the low refractive index layer (for example, the InP layer of the reflection portion 30, i.e., the high refractive index layer (the semiconductor layer 32) of the reflection portion 30) in each of the first to third examples is larger than the refractive index difference between the low refractive index layer (for example, the InP layer) of the reflection portion 30 and the layer (the InGaAsP layer of the reflection portion 30, i.e., the high refractive index layer of the reflection portion 30) adjacent to the low refractive index layer in the comparative example. Therefore, the coupling efficiency of light from the semiconductor optical gain device 1 to the optical waveguide chip 6 (see FIG. 46) is improved.

Furthermore, from the first to third examples and the comparative example, it can be seen that if the reflection portion 30 includes a plurality of air layers 31, the reflectance of the reflection portion 30 with respect to the second diffraction light 19 is further improved. Therefore, the coupling efficiency of light from the semiconductor optical gain device 1 to the optical waveguide chip 6 (see FIG. 46) is further improved.

The effects of the semiconductor optical gain device 1 according to the present embodiment will be described.

The semiconductor optical gain device 1 according to the present embodiment includes a substrate 10, an active portion 2 formed on the substrate 10, and a passive portion 3 formed on the substrate 10. The active portion 2 includes an active layer 12. The passive portion 3 includes a first core layer 23 optically coupled to the active layer 12, a reflection portion 30, and a top surface 27 opposite to the substrate 10 with respect to the first core layer 23. The first core layer 23 is formed with a first grating coupler 24. The first grating coupler 24 diffracts light 17 output from the active layer 12 to generate a first diffraction light 18 traveling from the first grating coupler 24 toward the top surface 27 and a second diffraction light 19 traveling from the first grating coupler 24 toward the substrate 10. The reflection portion 30 is disposed between the first grating coupler 24 and the substrate 10 to reflect the second diffraction light 19 toward the top surface 27 of the passive portion 3, and includes at least one air layer 31.

Since the semiconductor optical gain device 1 includes the reflection portion 30, not only the first diffraction light 18 but also the second diffraction light 19 is emitted from the top surface 27 of the passive portion 3. The first diffraction light 18 and the second diffraction light 19 are emitted from the semiconductor optical gain device 1 without travelling through the substrate 10 having the largest thickness variation in the semiconductor optical gain device 1. Therefore, the variation in the position of the first diffraction light 18 and the second diffraction light 19 emitted from the semiconductor optical gain device 1 is reduced. The mounting accuracy of the semiconductor optical gain device 1 on the optical waveguide chip 6 can be relaxed. In addition, since the reflection portion 30 includes at least one air layer 31, the reflectance of the reflection portion 30 with respect to the second diffraction light 19 is increased. Therefore, the coupling efficiency of light from the semiconductor optical gain device 1 to the optical waveguide chip 6 can be improved.

In the semiconductor optical gain device 1 of the present embodiment, at least one air layer 31 includes a plurality of air layers 31. The reflection portion 30 is a multilayer reflection film that includes the plurality of air layers 31 and at least one semiconductor layer 32.

Since the reflection portion 30 includes a plurality of air layers 31, the reflectance of the reflection portion 30 with respect to the second diffraction light 19 is further increased. Therefore, the coupling efficiency of light from the semiconductor optical gain device 1 to the optical waveguide chip 6 can be further improved.

In the semiconductor optical gain device 1 of the present embodiment, the reflection portion 30 is a distributed Bragg reflector.

Therefore, the mounting accuracy of the semiconductor optical gain device 1 on the optical waveguide chip 6 can be relaxed, and the coupling efficiency of light from the semiconductor optical gain device 1 to the optical waveguide chip 6 can be improved.

In the semiconductor optical gain device 1 of the present embodiment, the first grating coupler 24 has a grating pitch of less than 0.58 μm.

Therefore, the second diffraction light 19 is emitted to the outside of the semiconductor optical gain device 1 without being totally reflected by the top surface 27 of the passive portion 3. Therefore, the coupling efficiency of light from the semiconductor optical gain device 1 to the optical waveguide chip 6 can be improved.

### Second Embodiment

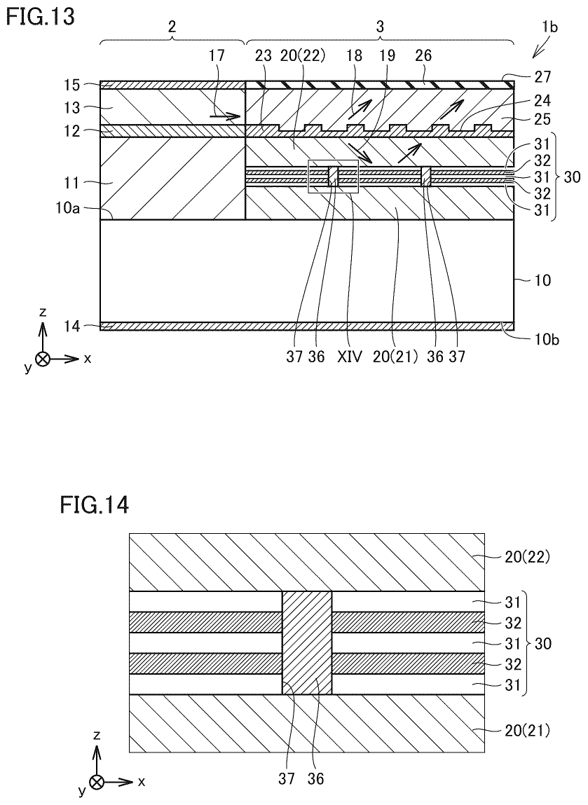

A semiconductor optical gain device 1b according to a second embodiment will be described with reference to FIGS. 13 and 14. The semiconductor optical gain device 1b of the present embodiment has the same configuration as the semiconductor optical gain device 1 of the first embodiment, but is different mainly in the following points.

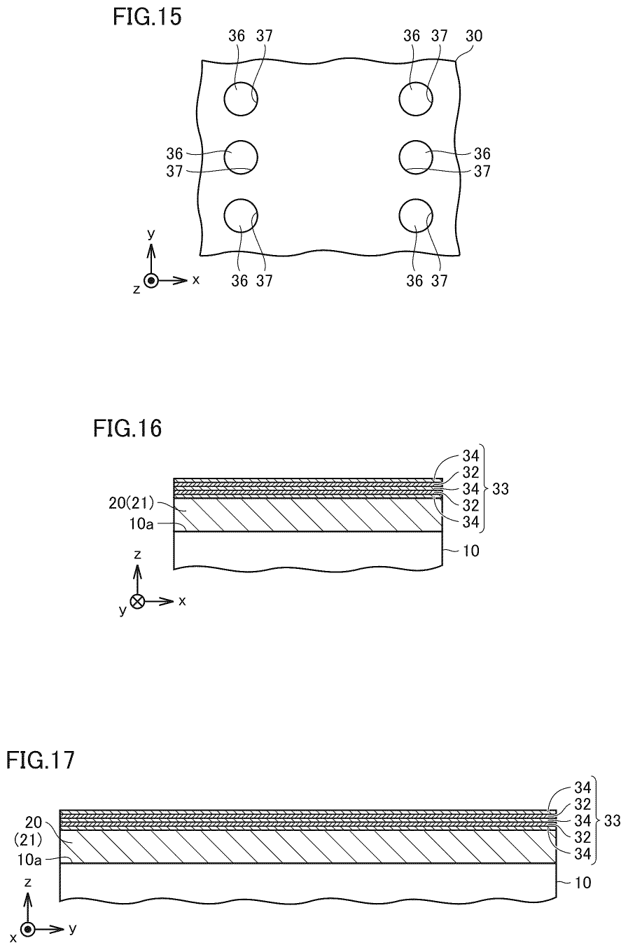

In the semiconductor optical gain device 1b, the passive portion 3 further includes a support member 36. The support member 36 extends from the first lower cladding sublayer 21 to the second lower cladding sublayer 22, penetrating through the air layer 31. The support member 36 supports the second lower cladding sublayer 22 and the semiconductor layer 32. As illustrated in FIG. 15, in a plan view of the top surface 27 of the passive portion 3, the support member 36 is disposed inside the reflection portion 30. Specifically, the reflection portion 30 is formed with a hole 37. the support member 36 is formed in the hole 37. A groove may be formed in the multilayer film 33 instead of the hole 37, and the support member 36 may be formed in the groove. The support member 36 is, for example, a support column or a support wall.

The support member 36 is formed of, for example, a semiconductor. The support member 36 may be formed of the same material as the semiconductor layer 32. The support member 36 may be formed of the same material as the lower cladding layer 20. The support member 36 may be formed of, for example, the same material as the first lower cladding sublayer 21 or the same material as the second lower cladding sublayer 22. The support member 36 is formed of, for example, a compound semiconductor such as InP or GaAs.

The number of the air layers 31 included in the reflection portion 30 is not limited to two or more, and may be one. In other words, the reflection portion 30 may include at least one air layer 31. When the number of the air layers 31 included in the reflection portion 30 is one, the reflection portion 30 may not include the semiconductor layer 32, and the support member 36 may support the second lower cladding sublayer 22.

An example method of manufacturing the passive portion 3 of the semiconductor optical gain device 1b of the present embodiment will be described with reference to FIGS. 16 to 25. The method of manufacturing the passive portion 3 of the semiconductor optical gain device 1b of the present embodiment includes the same steps as the method of manufacturing the passive portion 3 of the semiconductor optical gain device 1 of the first embodiment, but is different from the method of manufacturing the passive portion 3 of the semiconductor optical gain device 1 of the first embodiment in the following points.

With reference to FIGS. 16 and 17, the first lower cladding sublayer 21 and the multilayer film 33 are formed on the main surface 10a of the substrate 10 by the same steps as those illustrated in FIGS. 3 and 4 in the method of manufacturing the passive portion 3 of the semiconductor optical gain device 1 according to the first embodiment.

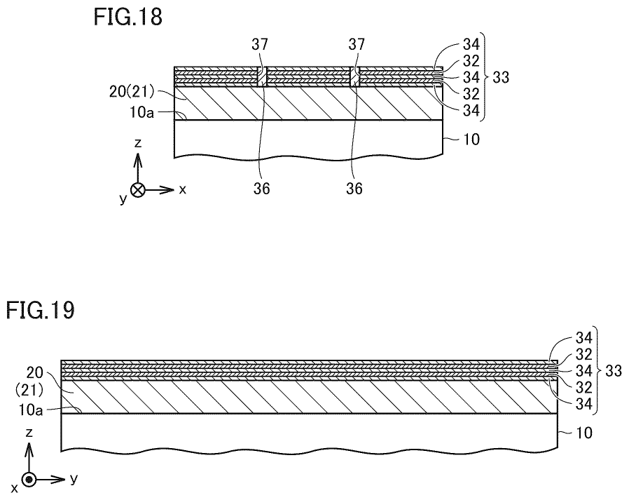

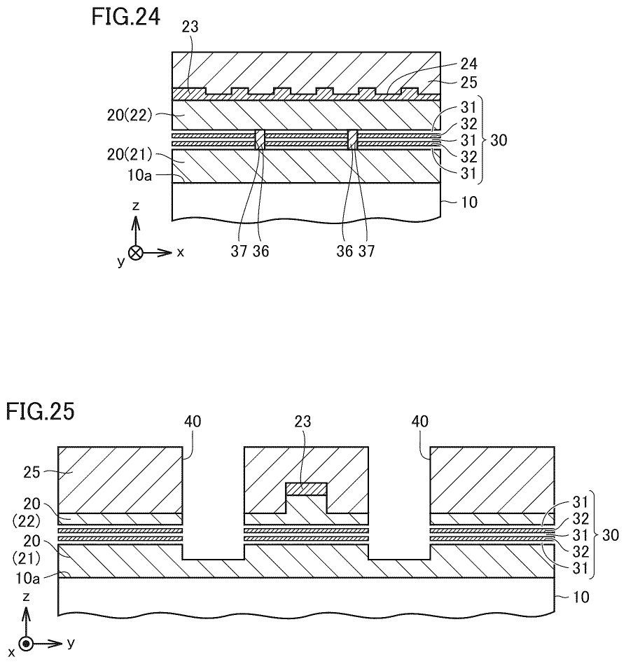

With reference to FIGS. 18 and 19, the multilayer film 33 is etched to form a hole 37 in the multilayer film 33. The support member 36 is formed in the hole 37 by, for example, epitaxial growth. Instead of the hole 37, a groove may be formed in the multilayer film 33, and the support member 36 may be formed in the groove. The support member 36 is formed inside the multilayer film 33. The support member 36 is formed of a material having a lower etching rate than the sacrificial layer 34 with respect to the etchant used in the etching steps illustrated in FIGS. 24 and 25. The support member 36 is formed of, for example, a compound semiconductor such as InP or GaAs.

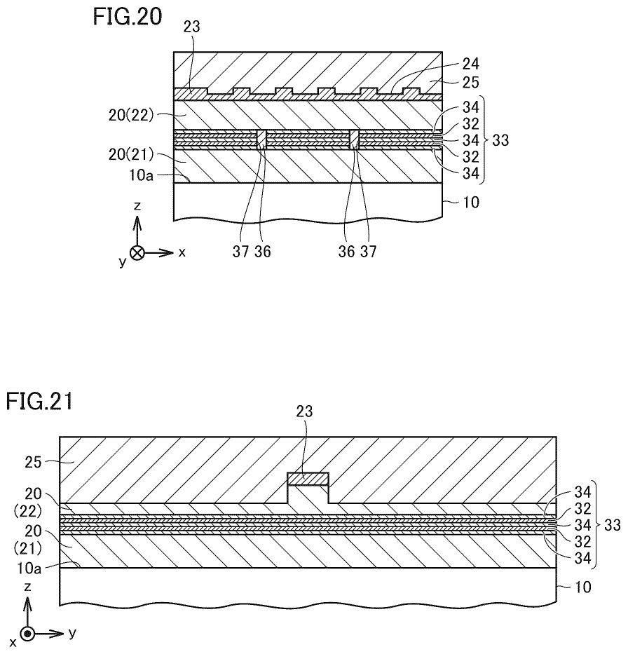

With reference to FIGS. 20 and 21, the second lower cladding sublayer 22, the first core layer 23, and the upper cladding layer 25 are formed on the multilayer film 33 and the support member 36 by the same steps as those illustrated in FIGS. 5 and 6 in the method of manufacturing the passive portion 3 of the semiconductor optical gain device 1 according to the first embodiment. The first core layer 23 is formed with a first grating coupler 24.

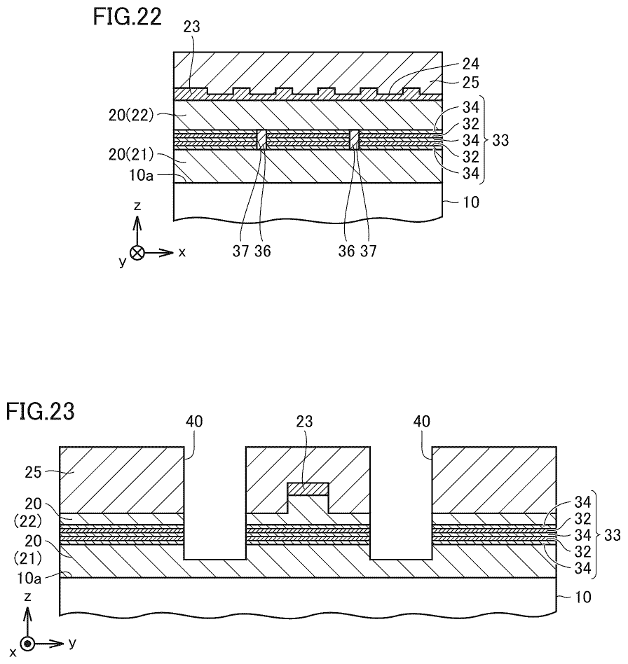

With reference to FIGS. 22 and 23, a groove 40 is formed on both sides of first core layer 23 by the same steps as those illustrated in FIGS. 7 and 8 in the method of manufacturing the passive portion 3 of the semiconductor optical gain device 1 according to the first embodiment. Holes may be formed instead of the groove 40. A part of the multilayer film 33 is exposed from the groove 40.

With reference to FIGS. 24 and 25, an etchant (for example, an etching solution) is introduced into the groove 40 by the same steps as those illustrated in FIGS. 9 and 10 in the method of manufacturing the passive portion 3 of the semiconductor optical gain device 1 according to the first embodiment, and thereby the sacrificial layer 34 of the multilayer film 33 is selectively etched by the etchant. Since the semiconductor layer 32 and the support member 36 have an etching rate lower than that of the sacrificial layer 34 with respect to the etchant, they are hardly etched by the etchant. The sacrificial layer 34 becomes the air layer 31, and the multilayer film 33 becomes the reflection portion 30. An insulating layer 26 is formed on the upper cladding layer 25 by, for example, chemical vapor deposition (CVD) or sputtering. Thus, the passive portion 3 of the semiconductor optical gain device 1b is obtained.

The semiconductor optical gain device 1b according to the present embodiment exhibits the follow effects in addition to the effects of the semiconductor optical gain device 1 according to the first embodiment.

In the semiconductor optical gain device 1b according to the present embodiment, the passive portion 3 includes a lower cladding layer 20 disposed between the first core layer 23 and the substrate 10 and a support member 36. The lower cladding layer 20 includes a first lower cladding sublayer 21 disposed between the reflection portion 30 and the substrate 10 and a second lower cladding sublayer 22 disposed between the reflection portion 30 and the first core layer 23. The support member 36 extends from the first lower cladding sublayer 21 to the second lower cladding sublayer 22 to support the second lower cladding sublayer 22, and is disposed inside the reflection portion 30 in a plan view of the top surface 27 of the passive portion 3.

The support member 36 improves the mechanical strength of the reflection portion 30. Thus, it is possible to prevent the semiconductor optical gain device 1b from being damaged during the manufacture of the semiconductor optical gain device 1b. Therefore, the manufacturing yield of the semiconductor optical gain device 1b is improved. In addition, it is possible to prevent the semiconductor optical gain device 1b from being damaged by thermal stress applied to the semiconductor optical gain device 1b during the long-term use of the semiconductor optical gain device 1b. Therefore, the lifetime of the semiconductor optical gain device 1b is prolonged.

In the semiconductor optical gain device 1b of the present embodiment, the passive portion 3 includes a lower cladding layer 20 disposed between the first core layer 23 and the substrate 10 and a support member 36. The lower cladding layer 20 includes a first lower cladding sublayer 21 disposed between the reflection portion 30 and the substrate 10 and a second lower cladding sublayer 22 disposed between the reflection portion 30 and the first core layer 23. The support member 36 extends from the first lower cladding sublayer 21 to the second lower cladding sublayer 22 to support the second lower cladding sublayer 22 and the at least one semiconductor layer 32, and is disposed inside the reflection portion 30 in a plan view of the top surface 27 of the passive portion 3.

The support member 36 improves the mechanical strength of the reflection portion 30. Thus, it is possible to prevent the semiconductor optical gain device 1b from being damaged during the manufacture of the semiconductor optical gain device 1b. Therefore, the manufacturing yield of the semiconductor optical gain device 1b is improved. In addition, it is possible to prevent the semiconductor optical gain device 1b from being damaged by thermal stress applied to the semiconductor optical gain device 1b during the long-term use of the semiconductor optical gain device 1b. Therefore, the lifetime of the semiconductor optical gain device 1b is prolonged.

### Third Embodiment

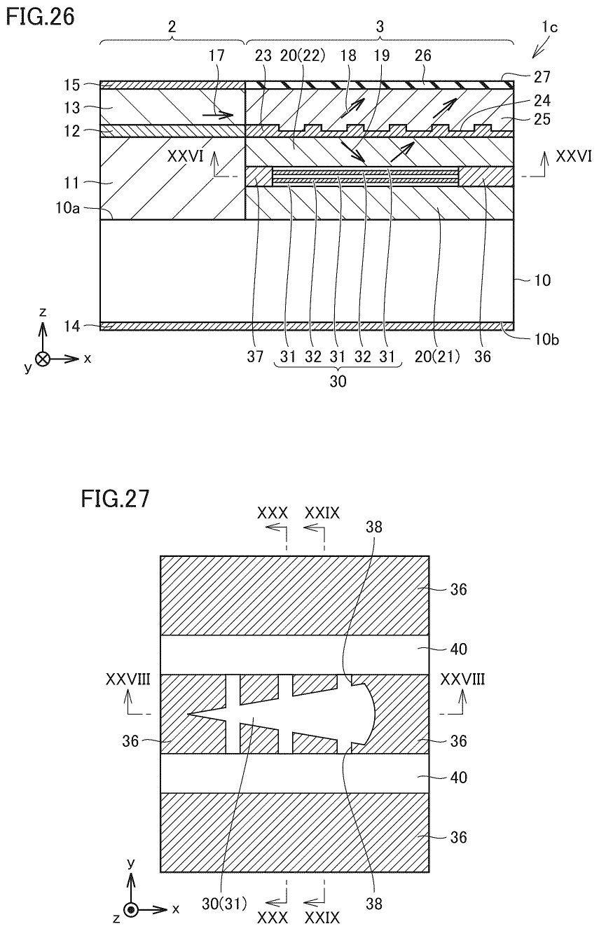

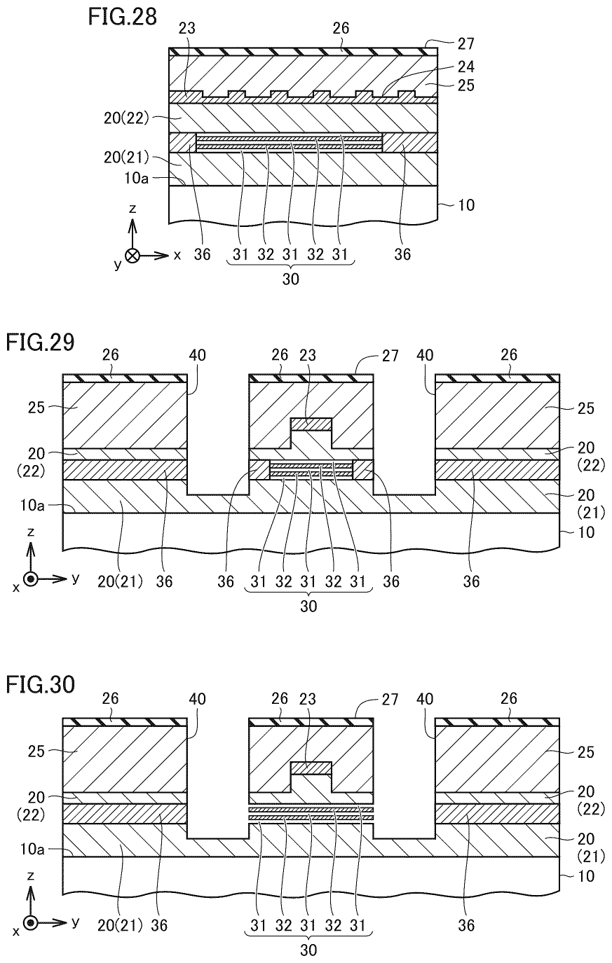

A semiconductor optical gain device 1c according to a third embodiment will be described with reference to FIGS. 26 to 30. The semiconductor optical gain device 1c of the present embodiment has the same configuration as the semiconductor optical gain device 1 of the first embodiment, but is different mainly in the following points.

In the semiconductor optical gain device 1c, in a plan view of the top surface 27 of the passive portion 3, the reflection portion 30 is smaller than the top surface 27 of the passive portion 3. In a plan view of the top surface 27 of the passive portion 3, the reflection portion 30 is smaller than the upper cladding layer 25. For example, in a plan view of the top surface 27 of the passive portion 3, the reflection portion 30 is selectively formed in a region where the second diffraction light 19 is distributed.

The passive part 3 further includes a support member 36. The support member 36 extends from the first lower cladding sublayer 21 to the second lower cladding sublayer 22. The support member 36 supports the second lower cladding sublayer 22 and the semiconductor layer 32. As illustrated in FIG. 27, the support member 36 is disposed around the reflection portion 30 in a plan view of the top surface 27 of the passive portion 3. The support member 36 is provided with a bore 38 communicating with the air layer 31 of the reflection portion 30. For example, the support member 36 is a wall, for example, and the bore 38 is provided in the wall. The air layer 31 and the semiconductor layer 32 constituting the reflection portion 30 are also provided in the bore 38.

The support member 36 may be formed of, for example, a semiconductor. The support member 36 may be formed of, for example, the same material as the semiconductor layer 32. The support member 36 may be formed of, for example, the same material as the lower cladding layer 20. The support member 36 may be formed of, for example, the same material as the first lower cladding sublayer 21 or the same material as the second lower cladding sublayer 22. The support member 36 is formed of, for example, a compound semiconductor such as InP or GaAs.

The number of the air layers 31 included in the reflection portion 30 is not limited to two or more, and may be one. In other words, the reflection portion 30 may include at least one air layer 31. When the number of the air layers 31 included in the reflection portion 30 is one, the reflection portion 30 may not include the semiconductor layer 32, and the support member 36 may support the second lower cladding sublayer 22.

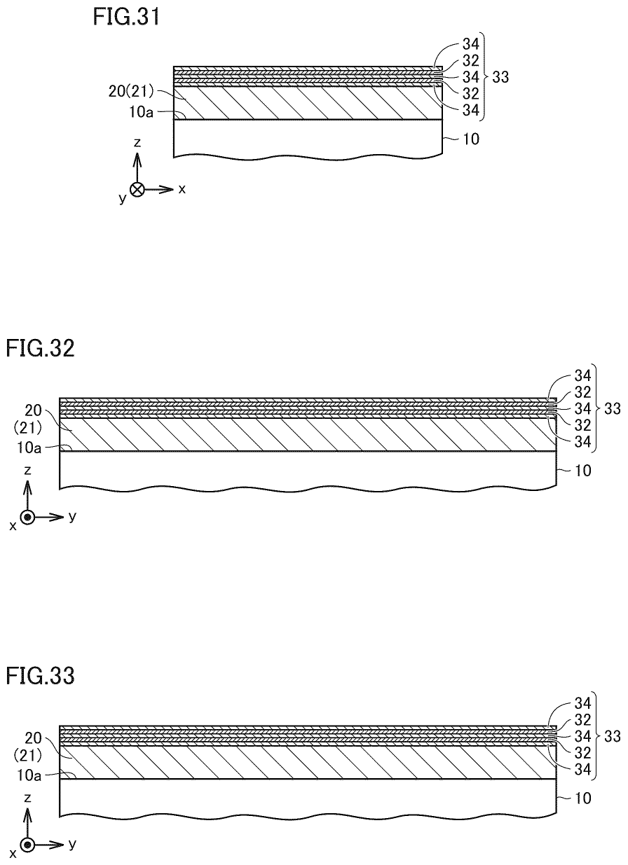

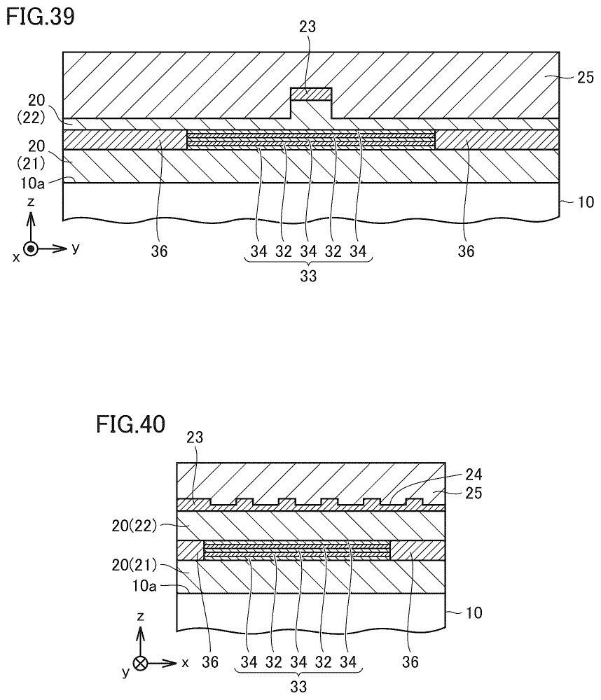

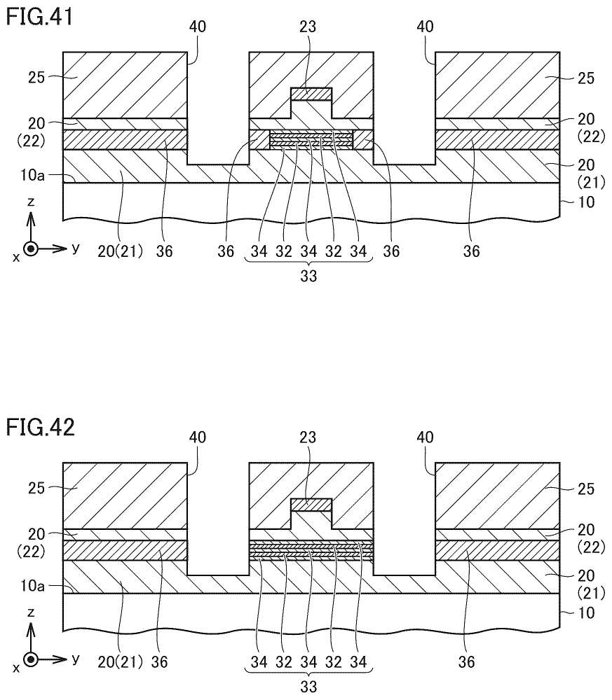

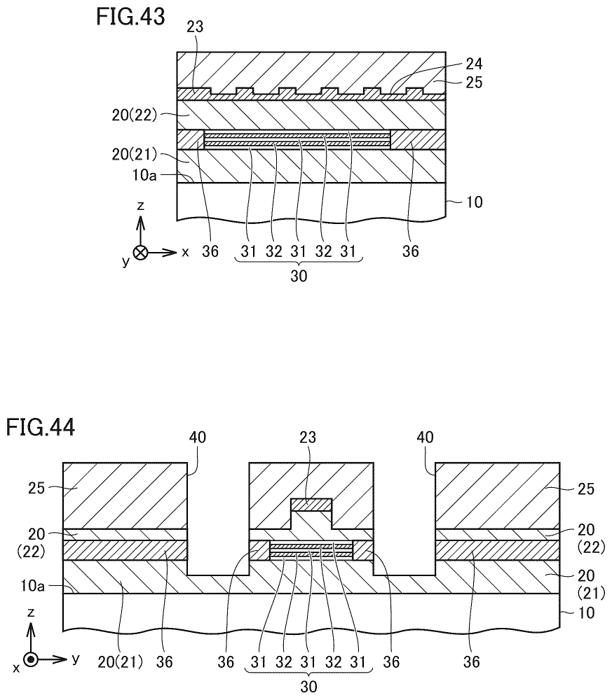

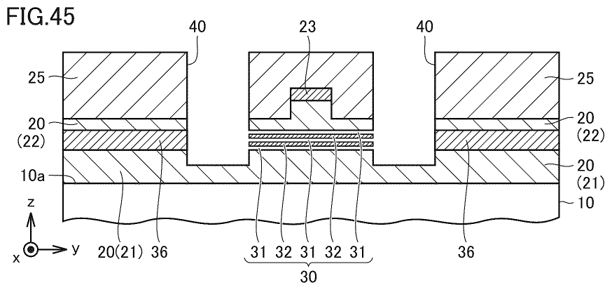

An example method of manufacturing the passive portion 3 of the semiconductor optical gain device 1c of the present embodiment will be described with reference to FIGS. 31 to 45. Each of FIG. 32, FIG. 35, FIG. 38, FIG. 41, and FIG. 44 is a partially enlarged cross-sectional view schematically illustrating a portion of the passive portion 3 that corresponds to that illustrated in FIG. 29. Each of FIG. 33, FIG. 36, FIG. 39, FIG. 42, and FIG. 45 is a partially enlarged cross-sectional view schematically illustrating a portion of the passive portion 3 that corresponds to that illustrated in FIG. 30. The method of manufacturing the passive portion 3 of the semiconductor optical gain device 1c of the present embodiment includes the same steps as the method of manufacturing the passive portion 3 of the semiconductor optical gain device 1 of the first embodiment, but is different from the method of manufacturing the passive portion 3 of the semiconductor optical gain device 1 of the first embodiment in the following points.

With reference to FIGS. 31 to 33, a first lower cladding sublayer 21 and a multilayer film 33 are formed on the main surface 10a of the substrate 10 by the same steps as those illustrated in FIGS. 3 and 4 in the method of manufacturing the passive portion 3 of the semiconductor optical gain device 1 of the first embodiment.

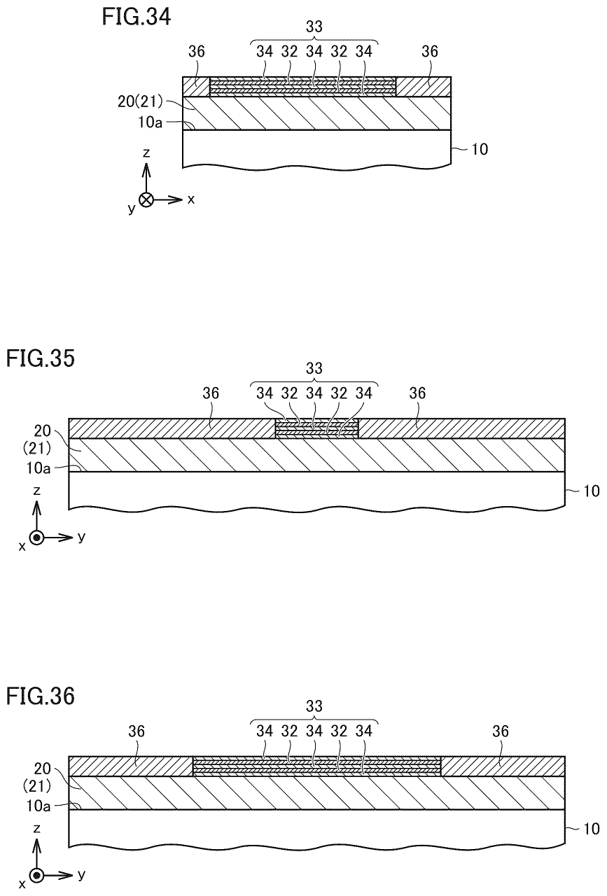

With reference to FIGS. 34 to 36, the multilayer film 33 is etched. The support member 36 is formed around the multilayer film 33 by, for example, epitaxial growth. The support member 36 is formed around the multilayer film 33. The support member 36 is provided with a bore 38 (see FIG. 27), and the multilayer film 33 is also provided in the bore 38. The support member 36 is formed of a material having a lower etching rate than the sacrificial layer 34 with respect to the etchant used in the etching steps illustrated in FIGS. 43 to 45. The support member 36 is formed of, for example, a compound semiconductor such as IrP or GaAs.

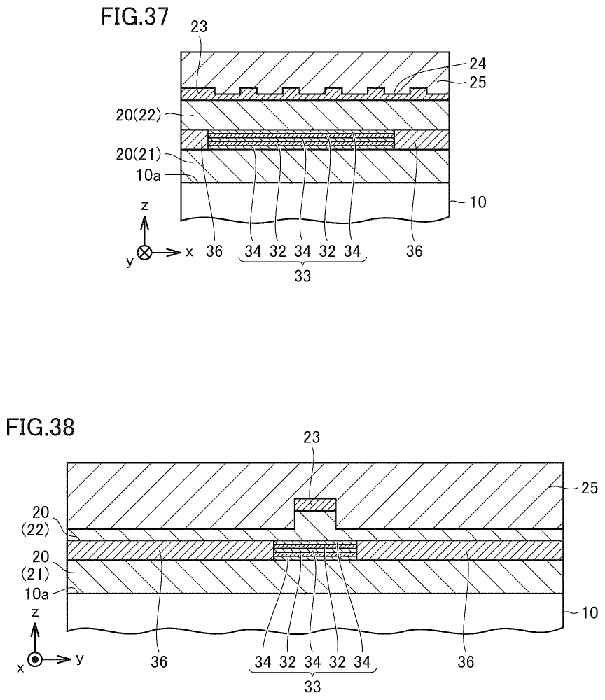

With reference to FIGS. 37 to 39, a second lower cladding sublayer 22, a first core layer 23, and an upper cladding layer 25 are formed on the multilayer film 33 and the support member 36 by the same steps as those illustrated in FIGS. 5 and 6 in the method of manufacturing the passive portion 3 of the semiconductor optical gain device 1 according to the first embodiment. The first core layer 23 is formed with a first grating coupler 24.

With reference to FIGS. 40 to 42, a groove 40 is formed on both sides of the first core layer 23 by etching the upper cladding layer 25, the second lower cladding sublayer 22, the multilayer film 33, the support member 36, and the first lower cladding sublayer 21 by the same steps as those illustrated in FIGS. 7 and 8 in the method of manufacturing the passive portion 3 of the semiconductor optical gain device 1 of the first embodiment. The groove 40 formed on both sides of the first core layer 23 is connected to the bores 38 of the support member 36. A part of the multilayer film 33 is exposed from the groove 40. Holes may be formed instead of the groove 40.

With reference to FIGS. 43 to 45, an etchant (for example, an etching solution) is introduced into the groove 40 by the same steps as those illustrated in FIGS. 9 and 10 in the method of manufacturing the passive portion 3 of the semiconductor optical gain device 1 according to the first embodiment, and thereby the sacrificial layer 34 of the multilayer film 33 is selectively etched by the etchant. The etchant flows into the support member 36 from the bore 38 of the support member 36 while etching the sacrificial layer 34. Since the semiconductor layer 32 and the support member 36 have an etching rate lower than that of the sacrificial layer 34 with respect to the etchant, they are hardly etched by the etchant. The sacrificial layer 34 becomes the air layer 31, and the multilayer film 33 becomes the reflection portion 30. The air layer 31 communicates with the bore 38 and the groove 40. The insulating layer 26 is formed on the upper cladding layer 25 by, for example, chemical vapor deposition (CVD) or sputtering. Thus, the passive portion 3 of the semiconductor optical gain device 1c is obtained.

The semiconductor optical gain device 1c according to the present embodiment exhibits the follow effects in addition to the effects of the semiconductor optical gain device 1 according to the first embodiment.

In the semiconductor optical gain device 1c according to the present embodiment, the passive portion 3 includes a lower cladding layer 20 disposed between the first core layer 23 and the substrate 10 and a support member 36. The lower cladding layer 20 includes a first lower cladding sublayer 21 disposed between the reflection portion 30 and the substrate 10 and a second lower cladding sublayer 22 disposed between the reflection portion 30 and the first core layer 23. The support member 36 extends from the first lower cladding sublayer 21 to the second lower cladding sublayer 22 to support the second lower cladding sublayer 22, and is disposed around the reflection portion 30 in a plan view of the top surface 27 of the passive portion 3.

The support member 36 improves the mechanical strength of the reflection portion 30. Thus, it is possible to prevent the semiconductor optical gain device 1c from being damaged during the manufacture of the semiconductor optical gain device 1c. Therefore, the manufacturing yield of the semiconductor optical gain device 1c is improved. In addition, it is possible to prevent the semiconductor optical gain device 1c from being damaged by thermal stress applied to the semiconductor optical gain device 1c during the long-term use of the semiconductor optical gain device 1c. Therefore, the lifetime of the semiconductor optical gain device 1c is prolonged.

In the semiconductor optical gain device 1c of the present embodiment, the passive portion 3 includes a lower cladding layer 20 disposed between the first core layer 23 and the substrate 10 and a support member 36. The lower cladding layer 20 includes a first lower cladding sublayer 21 disposed between the reflection portion 30 and the substrate 10 and a second lower cladding sublayer 22 disposed between the reflection portion 30 and the first core layer 23. The support member 36 extends from the first lower cladding sublayer 21 to the second lower cladding sublayer 22 to support the second lower cladding sublayer 22 and the at least one semiconductor layer 32, and is disposed around the reflection portion 30 in a plan view of the top surface 27 of the passive portion 3.

The support member 36 improves the mechanical strength of the reflection portion 30. Thus, it is possible to prevent the semiconductor optical gain device 1c from being damaged during the manufacture of the semiconductor optical gain device 1c. Therefore, the manufacturing yield of the semiconductor optical gain device 1c is improved. In addition, it is possible to prevent the semiconductor optical gain device 1c from being damaged by thermal stress applied to the semiconductor optical gain device 1e during the long-term use of the semiconductor optical gain device 1c. Therefore, the lifetime of the semiconductor optical gain device 1c is prolonged.

In the semiconductor optical gain device 1c of the present embodiment, the support member 36 is provided with a bore 38 communicating with at least one air layer 31.

Therefore, even when the support member 36 is disposed around the reflection portion 30 in a plan view of the top surface 27 of the passive portion 3, the etchant flows into the support member 36 from the bore 38 of the support member 36 while etching the sacrificial layer 34. The reflection portion 30 including the air layer 31 can be easily manufactured.

### Fourth Embodiment

An optical semiconductor apparatus 5 according to a fourth embodiment will be described with reference to FIG. 46. The optical semiconductor apparatus 5 includes a semiconductor optical gain device 1 of the first embodiment, an optical waveguide chip 6, and a bonding member 50.

The optical waveguide chip 6 includes a substrate 43, a lower cladding layer 44, a second core layer 45, an upper cladding layer 47, and a top surface 48.

The substrate 43 is, for example, a semiconductor substrate such as a Si substrate. The substrate 43 may be formed of a material different from that of the substrate 10.

The lower cladding layer 44 is formed on the substrate 43 by, for example, chemical vapor deposition (CVD) or sputtering. The lower cladding layer 44 is disposed between the second core layer 45 and the substrate 43. The lower cladding layer 44 is, for example, a silicon oxide layer (SiO₂ layer).

The second core layer 45 is formed on the lower cladding layer 44 by, for example, chemical vapor deposition (CVD) or sputtering. The second core layer 45 has a higher refractive index than the lower cladding layer 44 and the upper cladding layer 47. The second core layer 45 is formed of, for example, a material different from that of the first core layer 23. The second core layer 45 is formed of, for example, silicon (Si) or silicon nitride (Si₃N₄). For example, each of the refractive index difference between the second core layer 45 and the upper cladding layer 47 and the refractive index difference between the second core layer 45 and the lower cladding layer 44 is larger than the refractive index difference between the first core layer 23 and the upper cladding layer 25 and larger than the refractive index difference between the first core layer 23 and the lower cladding layer 20. The confinement of light to the second core layer 45 in the optical waveguide chip 6 may be stronger than the confinement of light to the first core layer 23 in the passive portion 3 chip.

The upper cladding layer 47 is formed on the second core layer 45 by, for example, chemical vapor deposition (CVD) or sputtering. The upper cladding layer 47 is, for example, a silicon oxide layer (SiO₂ layer). The top surface 48 of the optical waveguide chip 6 is a surface of the optical waveguide chip 6 opposite to the substrate 43. The upper cladding layer 47 includes the top surface 48.

The second core layer 45 is formed with a second grating coupler 46 optically coupled to the first grating coupler 24. The second grating coupler 46 is formed by, for example, etching the second core layer 45. The first diffraction light 18 and the second diffraction light 19 are coupled to the second grating coupler 46 and propagate through the second core layer 45.

The semiconductor optical gain device 1c is flip-chip mounted on the optical waveguide chip 6 using the bonding member 50. Specifically, the top surface 27 of the passive portion 3 is disposed to face the optical waveguide chip 6 (more specifically, the top surface 48). The bonding member 50 is, for example, an Au bump or solder.

The operations of the optical semiconductor apparatus 5 will be described. When a current is injected into the active layer 12 from the electrodes 14 and 15, an induced emission phenomenon occurs in the active layer 12. Light 17 is output from the active layer 12. The light 17 is coupled to the first core layer 23 and propagates through the first core layer 23. The first grating coupler 24 diffracts the light 17 to generate a first diffraction light 18 and a second diffraction light 19. The reflection portion 30 reflects the second diffraction light 19 toward the top surface 27 of the passive portion 3. The first diffraction light 18 and the second diffraction light 19 are emitted from the top surface 27 of the passive portion 3. The first diffraction light 18 and the second diffraction light 19 are coupled to the second grating coupler 46 and propagate through the second core layer 45.

In a modification of the present embodiment, the optical semiconductor apparatus 5 may include the semiconductor optical gain device 1b according to the second embodiment or the semiconductor optical gain device 1c according to the third embodiment instead of the semiconductor optical gain device 1 according to the first embodiment.

The effects of the optical semiconductor apparatus 5 of the present embodiment will be described.

The optical semiconductor apparatus 5 of the present embodiment includes a semiconductor optical gain device 1, 1b or 1c, and an optical waveguide chip 6 disposed to face the top surface 27 of the passive portion 3. The optical waveguide chip 6 includes a second core layer 45. The second core layer 45 is formed with a second grating coupler 46 optically coupled to the first grating coupler 24.

Therefore, the mounting accuracy of the semiconductor optical gain device 1, 1b or 1c on the optical waveguide chip 6 can be relaxed, and the coupling efficiency of light from the semiconductor optical gain device 1, 1b or 1 c to the optical waveguide chip 6 can be improved.

In the optical semiconductor apparatus 5 of the present embodiment, the first core layer 23 is formed of a compound semiconductor. The second core layer 45 is formed of silicon (Si) or silicon nitride (Si₃N₄).

Therefore, even when the second core layer 45 is formed of a material different from that of the first core layer 23, the mounting accuracy of the semiconductor optical gain device 1, 1b or 1c on the optical waveguide chip 6 can be relaxed, and the coupling efficiency of light from the semiconductor optical gain device 1, 1b or 1c to the optical waveguide chip 6 can be improved.

It should be understood that the first embodiment to the fourth embodiment disclosed herein are illustrative and non-restrictive in all respects. At least two of the presently disclosed first to fourth embodiments may be combined as long as there is no contradiction. The scope of the present invention is defined by the terms of the claims rather than the description of the embodiments above, and is intended to include any modifications within the scope and meaning equivalent to the terms of the claims.

### REFERENCE SIGNS LIST

1, 1b, 1c: semiconductor optical gain device; 2: active portion; 3: passive portion; 5: optical semiconductor apparatus; 6: optical waveguide chip; 10: substrate; 10a, 10b: main surface; 11: lower cladding layer; 12: active layer; 13: upper cladding layer; 14, 15: electrode; 17: light; 18: first diffraction light; 19: second diffraction light; 20: lower cladding layer; 21: first lower cladding sublayer; 22: second lower cladding sublayer; 23: first core layer; 24: first grating coupler; 25: upper cladding layer; 26: insulating layer; 27: top surface; 30: reflection portion; 31: air layer; 32: semiconductor layer; 33: multilayer film; 34: sacrificial layer; 36: support member; 37: hole; 38: bore; 40: groove; 43: substrate; 44: lower cladding layer; 45: second core layer; 46: second grating coupler; 47: upper cladding layer; 48: top surface; 50: bonding member.

1. A semiconductor optical gain device comprising:
a substrate;
an active portion formed on the substrate; and
a passive portion formed on the substrate,
the active portion includes an active layer and an electrode, a current being injected from the electrode,
the passive portion includes a first core layer optically coupled to the active layer, a reflection portion, and a top surface opposite to the substrate with respect to the first core layer,
the first core layer is formed with a first grating coupler,
the first grating coupler diffracts light output from the active layer to generate a first diffraction light traveling from the first grating coupler toward the top surface and a second diffraction light traveling from the first grating coupler toward the substrate,
the reflection portion is formed only in the passive portion and disposed between the first grating coupler and the substrate to reflect the second diffraction light toward the top surface, and includes at least one air layer.

2. The semiconductor optical gain device according to claim 1, wherein
the at least one air layer includes a plurality of air layers, and
the reflection portion is a multilayer reflection film that includes the plurality of air layers and at least one semiconductor layer.

3. The semiconductor optical gain device according to claim 2, wherein
the reflection portion is a distributed Bragg reflector.

4. The semiconductor optical gain device according to claim 1, wherein
the passive portion includes a lower cladding layer disposed between the first core layer and the substrate and a support member,
the lower cladding layer includes a first lower cladding sublayer disposed between the reflection portion and the substrate and a second lower cladding sublayer disposed between the reflection portion and the first core layer, and
the support member extends from the first lower cladding sublayer to the second lower cladding sublayer to support the second lower cladding sublayer, and is disposed inside the reflection portion in a plan view of the top surface.

5. The semiconductor optical gain device according to claim 2, wherein
the passive portion includes a lower cladding layer disposed between the first core layer and the substrate and a support member,
the lower cladding layer includes a first lower cladding sublayer disposed between the reflection portion and the substrate and a second lower cladding sublayer disposed between the reflection portion and the first core layer, and
the support member extends from the first lower cladding sublayer to the second lower cladding sublayer to support the second lower cladding sublayer and the at least one semiconductor layer, and is disposed inside the reflection portion in a plan view of the top surface.

6. The semiconductor optical gain device according to claim 1,
the passive portion includes a lower cladding layer disposed between the first core layer and the substrate and a support member,
the lower cladding layer includes a first lower cladding sublayer disposed between the reflection portion and the substrate and a second lower cladding sublayer disposed between the reflection portion and the first core layer, and
the support member extends from the first lower cladding sublayer to the second lower cladding sublayer to support the second lower cladding sublayer, and is disposed around the reflection portion in a plan view of the top surface.

7. The semiconductor optical gain device according to claim 2, wherein
the passive portion includes a lower cladding layer disposed between the first core layer and the substrate and a support member,
the lower cladding layer includes a first lower cladding sublayer disposed between the reflection portion and the substrate and a second lower cladding sublayer disposed between the reflection portion and the first core layer, and
the support member extends from the first lower cladding sublayer to the second lower cladding sublayer to support the second lower cladding sublayer and the at least one semiconductor layer, and is disposed around the reflection portion in a plan view of the top surface.

8. The semiconductor optical gain device according to claim 6, wherein
the support member is provided with a bore communicating with the at least one air layer.

9. The semiconductor optical gain device according to claim 1, wherein
the first grating coupler has a grating pitch of less than 0.58 μm.

10. An optical semiconductor apparatus comprising:
the semiconductor optical gain device according to claim 1; and
an optical waveguide chip disposed to face the top surface,
the optical waveguide chip includes a second core layer, and
the second core layer is formed with a second grating coupler optically coupled to the first grating coupler.

11. The optical semiconductor apparatus according to claim 10, wherein
the first core layer is formed of a compound semiconductor, and
the second core layer is formed of silicon or silicon nitride.
